(19) United States
(12) Patent Application Publication
(10) Pub. No.: US 2007/0159841 A1
(43) Pub. Date: Jul. 12, 2007

(54) LED fiber decorative lamp structure

(76) Inventors: Juilin Huang, Qi-Shi Town (CN); MengChi Hsu, Guangdong (CN)

Correspondence Address: ROSENBERG, KLEIN & LEE, 3458 ELLICOTT CENTER DRIVE-SUITE 101, ELLICOTT CITY, MD, 21043, US

(21) Appl. No.: 11/396,686

(22) Filed: Apr. 4, 2006

(30) Foreign Application Priority Data
Jan. 10, 2006 (CN) 200620000229.6

(51) Int. Cl. H01L 33/00

(52) U.S. Cl. 362/555

(57) ABSTRACT

A LED fiber decorative lamp structure has a base and a plurality of transparence devices mounted on the base to form the whole shape of the LED fiber decorative lamp structure. A plurality of LED luminous sections is fixed on the base, and each LED luminous section has a plurality of LED illuminating settings. Each LED illuminating setting has a hollow fixation device fixed on the base and a fiber cluster having a plurality of fibers colligated together. The colligated end of the fiber cluster being inserted into the hollow fixation device, each fiber of the non-colligated end being set inside the transparence device. The LED is inserted into the other end of the fixation device and the head of the LED being besides the colligated end of the fiber cluster.

### FIELD OF THE INVENTION

The present invention relates to a kind of decorative lamp, especially a fiber decorative lamp structure with a special illumination effect composed of a base and the transparence devices, which installs multi-section LED illuminating devices in different positions.

### BACKGROUND OF THE INVENTION

Presently, the structure of the traditional fiber decorative lamp is quite complex. Take the Christmas tree as an example, like FIG. 1, the single light source and single section lighting fiber Christmas tree 10 has a color disk that installs a plurality of certain length fiber 11 and color disk 12 is connected to it; color disk 12 turns under motor 14 and the light source of color disk 12 is provided by the halogen Lamp 13 under it; when motor 14 turns, it will drive color disk 12 and the light source of halogen lamp 13 to let fiber 11 change colors. Because adopting single light source, halogen lamp 13 is extremely power consuming; therefore, long time using can easily cause high temperature or burning and motor 14 turning also generates noise.

In order to lower the halogen lamp long time working burning risk, it is suggested to adopt LED as the fiber light source. Though it can solve the burning risk and has lower power consuming, normally the non-transparence material is adopted, take the Christmas tree as an example, its green leaves adopt the non-transparence material, therefore, the LED light can only be transmitted through the fiber, which cause the light appears bleak and the decorative effects is weakened greatly.

The prior decorative lamp has many drawbacks in structure design and cause troubles and inconveniences in using, so improvements are needed.

### SUMMARY OF THE INVENTION

The present invention offers a new LED fiber decorative lamp structure having LED, transparence device and fiber. Use the LED light, through the fiber transmitting and the transparence and refraction effects of the transparence device to let the whole decorative lamp illuminate, which has the neon lamp luminous effects.

A LED fiber decorative lamp structure, comprising:
a base;
a plurality of transparence devices mounted on the base to form the whole shape of the LED fiber decorative lamp structure; and
a plurality of LED luminous sections fixed on the base, and each LED luminous section having a plurality of LED illuminating settings, and each LED illuminating setting comprising:
   a hollow fixation device fixed on the base;
   a fiber cluster having a plurality of fibers colligated together, the colligated end of the fiber cluster being inserted into one end of the hollow fixation device, each fiber of the non-colligated end being set inside the transparence device; and
      a LED inserted into the other end of the fixation device and the head of the LED being besides the colligated end of the fiber cluster.

The whole shape of the LED fiber decorative lamp structure can be image of animal.

The whole shape of the LED fiber decorative lamp structure can be image of Santa Claus.

The whole shape of the LED fiber decorative lamp structure can be image of Christmas tree.

The whole shape of the LED fiber decorative lamp structure can be image of Angell.

The fixation device comprises a tightening sleeve fixed on the base and two sleeves jointed together to form a protective cover, the LED and the fiber cluster being installed inside the protective cover, and the protective cover being fixed on the tightening sleeve.

The tightening sleeve and the protective cover have a big end and a small end, the small end of the protective cover being inserted into the big end of the tightening sleeve and being riveted with the small end of the tightening sleeve.

The LED luminous sections are connected together with an electrical apparatus property.

The LED luminous sections are connected to an outside power through wires and plugs.

The supporting device set between the base and a floorboard .

The base, according to number of the LED luminous sections, can be separated into a plurality of sub-bases connected together to form the base.

The transparence devices are made of transparence plastic materials.

The present invention adopts LED as the light source, with the fiber transmitting and uses the transparence and refraction effects of the transparence device to let the whole decorative lamp to illuminate, which has a special illuminating effect. Also, the present invention has the multi-section LED illuminating devices installed in different positions, which has the neon lamp luminous effects.

### BRIEF DESCRIPTION OF THE DRAWINGS

FIG. 1 is the perspective of the current technology based fiber decorative lamp structure.

FIG. 2 is the perspective of the invention LED fiber decorative lamp structure used in the Christmas tree.

FIG. 3 is the section view of the LED luminous section structure 3 in FIG. 2

FIG. 4 is the exploded view of the LED luminous device in the LED luminous section of this invention new LED fiber decorative lamp structure.

FIG. 5 is the perspective of LED luminous device protective cover, fiber and LED assembled together but not the tightening devices in this invention LED fiber decorative lamp structure.

FIG. 6 is the perspective of the LED luminous device complete assembly in this invention LED fiber decorative lamp structure

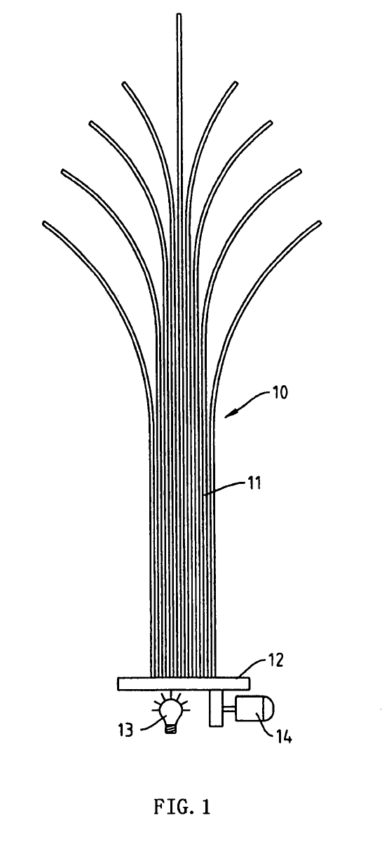

### DESCRIPTION OF THE PREFERRED EMBODIMENT

Following are the detail descriptions of this invention

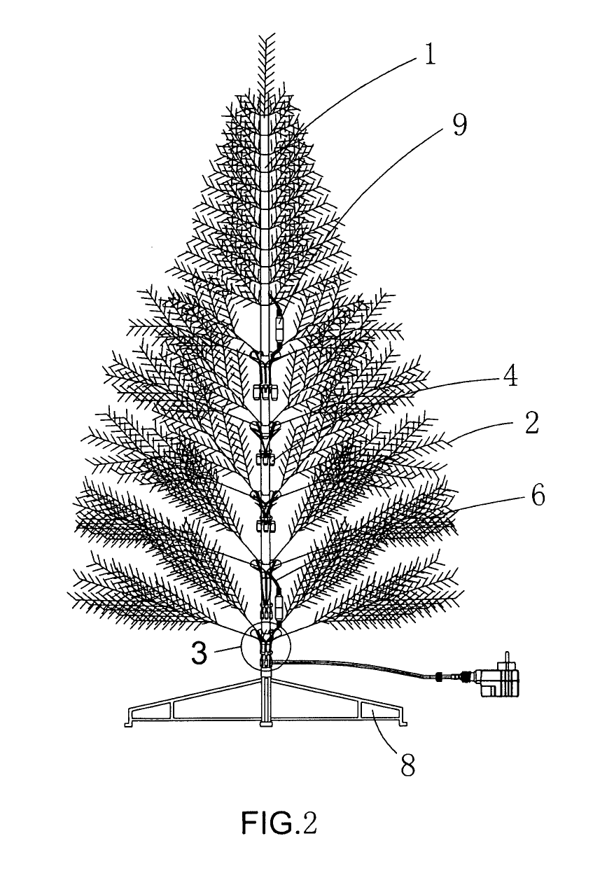

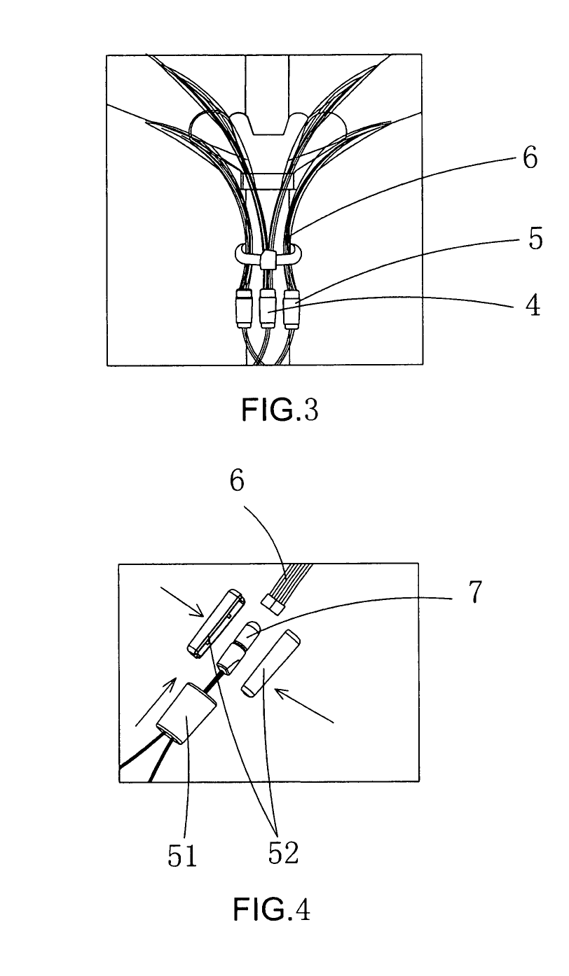

Like what showed from FIGS. 2 to 6, a LED fiber lamp structure comprises a base 1, a plurality of transparence devices 2 and a plurality of LED luminous section 8.

Base 1 can be placed on the ground for supporting. In this example of the Christmas tree, the base 1 is a trunk and several braches. A supporting device 8 can be set between the base and the ground, which enables the base 1 more stable.

A plurality of transparence devices 2 are mount on base 1 and form the whole shape of the LED fiber decorative lamp structure. The whole shape of the LED fiber decorative lamp structure can be image of animal, Christmas tree Santa Claus or Angell and so on. The animal can be deer, tiger, bear, fur seal or penguin etc. In this example, the transparence devices can be made into the Christmas tree branches and leaves with the transparence materials, and use sticking or the other method to fix them on base 1 to form a Christmas tree. In the other examples, the base can be made into straight or bend member, and the transparence devices can be made into fur style etc. Since plastic has the light weight, good tenacity, easy mold and low costs advantages, it is being widely used in modern industrial and commodities, especially its good transparency, high abrasion proof components and good impact resistance firmware. Currently, the common transparency plastic in the market are the PMMA, PC, PET, transparency nylon, AS and PSF etc.

The transparent plastic adopted by this invention must have high transparency, then a certain strengthen and abrasion proof abilities, impact resistance, good heat resistance, excellent chemical resistance and low water absorption rate, only then it can satisfy the transparency and the long term unchangeable requirements in using.

A plurality of LED luminous sections 3 can be fixed on the base 1 in a certain space and each LED luminous section 3 comprises a plurality of LED luminous device 4. Use electrical apparatus 9 electric property to connect the LED luminous section, e.g, the connector lug and electric cable electric property should be connected together to realize the electric control LED luminous section individual lightening, group lightening or the twinkle effects. One or a plurality of the LED luminous sections connected to an outside power through cable and plug. Since there are a plurality of luminous sections 3, the base can be separated into a plurality of sub bases. The LED luminous sections can be installed on the combination part of the sub-base to block them. Of course, a plurality of LED luminous sections 3 can be installed on the other positions of the base. During transporting and storing this invention, it can be disassembled and folded together in sections to save space.

LED luminous 4 comprises a hollow fixation device 5, a fiber cluster 6 and a LED 7. The hollow fixation device 5 is fixed on the base. Fiber cluster 6 has the ends of a plurality of fibers colligated together. The colligated end should be inserted into one end of the hollow fixation device and the non-colligated end of each fiber can be installed inside transparence device 2. LED 7 is inserted into the other end of the fixation device and the LED head of LED besides the colligated end of fiber cluster.

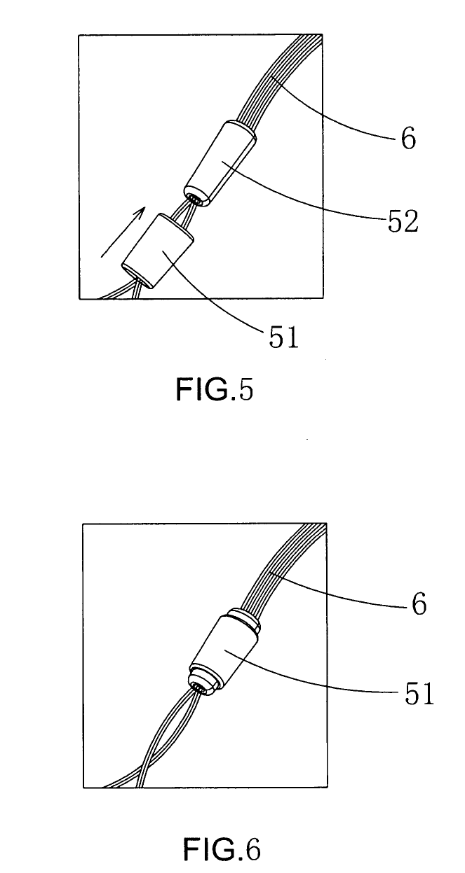

Like what showed in FIGS. 4 and 5, hollow fixation device 5 comprises a tightening sleeve 51 fixed on the base. Two sleeves joint together form a complete protective cover 52. The LED and the fiber cluster are placed inside the protective cover in accordance of the FIG. 4 arrow. The protective cover is stabled inside the tightening sleeve. Both the tightening sleeve 51 and the protective cover 52 are also a big end and a small end structure. Like the arrow in FIG. 5 shows, small end of protective cover 52 is inserted into big end of tightening sleeve 51 and is riveted small end of tightening sleeve 51. Despite the stable function of the tightening sleeve 51, it can protect the inside fiber cluster 6 and LED 7 as the protective cover 52 and prevent dust, water and electric leakage.

After electrified this invention, since each LED luminous section is connected with the connector lug electric property, then each LED luminous section shines; therefore, the light will shine on the colligated end of the fiber cluster and it is transmitted out through the fiber. Each non-colligated fiber will shoot out lights too since the fibers are located on both the top and bottom of the lamp; therefore, the whole lamp gets light spots. Since the transparence material is adopted, LED light will be transmitted out in the Christmas tree trunk and it is extremely attractive with the refraction effects of the material. In addition, LED and the transparence material can adopt all kinds of colors and different combinations according to different styles, which can give you a prismy and a neon lamp fascinating effect.

What described above is just the invention better complement example, but its claims scopes cannot be limited as it. For the common technicians who are familiar with this technology, other relative changes and modifications can be carried out upon this invention new technology plan and structure, but, of course, must not depart from the claim scope.

What is claimed is:

1. A LED fiber decorative lamp structure, comprising:
a base;
a plurality of transparence devices mounted on said base to form the whole shape of said LED fiber decorative lamp structure; and
a plurality of LED luminous sections fixed on said base, and each LED luminous section having a plurality of LED illuminating settings, and each LED illuminating setting comprising:
a hollow fixation device fixed on said base;
a fiber cluster having a plurality of fibers colligated together, the colligated end of said fiber cluster being inserted into said hollow fixation device, each fiber of the non-colligated end being set inside said transparence device; and
a LED inserted into the other end of said fixation device and the head of said LED being besides said colligated end of said fiber cluster.

2. The LED fiber decorative lamp structure of claim 1, wherein the whole shape of said LED fiber decorative lamp structure can be image of animal.

3. The LED fiber decorative lamp structure of claim 1, wherein the whole shape of said LED fiber decorative lamp structure can be image of Santa Claus.

4. The LED fiber decorative lamp structure of claim 1, wherein the whole shape of said LED fiber decorative lamp structure can be image of Christmas tree.

5. The LED fiber decorative lamp structure of claim 1, wherein the whole shape of said LED fiber decorative lamp structure can be image of Angell.

6. The LED fiber decorative lamp structure of claim 1 wherein said fixation device comprises a tightening sleeve fixed on said base and two sleeves jointed together to form a protective cover, said LED and said fiber cluster being installed inside said protective cover, and said protective cover being fixed on said tightening sleeve.

7. The LED fiber decorative lamp structure of claim 6, wherein both said tightening sleeve and said protective cover have a big end and a small end, said small end of said protective cover being inserted into said big end of said tightening sleeve and being riveted with said small end of said tightening sleeve.

8. The LED fiber decorative lamp structure of claim 1, wherein said LED luminous sections are connected together with an electrical apparatus property.

9. The LED fiber decorative lamp structure of claim 1, wherein said LED luminous sections are connected to an outside power through wires and plugs.

10. The LED fiber decorative lamp structure of claim 1, further comprising a supporting device set between said base and a floorboard.

11. The LED fiber decorative lamp structure of claim 1, wherein said base, according to number of the LED luminous sections, can be separated into a plurality of sub-bases connected together to form said base.

12. The LED fiber decorative lamp structure of claim 1 wherein said transparence devices is made of transparence plastic materials.
